(19) United States
(12) Patent Application Publication
(10) Pub. No.: US 2016/0093742 A1
(43) Pub. Date: Mar. 31, 2016

(54) SEMICONDUCTOR DEVICE

(71) Applicant: KABUSHIKI KAISHA TOSHIBA, Tokyo (JP)

(72) Inventors: Hisayo MOMOSE, Yokohama Kanagawa (JP); Tatsuya OHGURO, Yokohama Kanagawa (JP); Tetsu MOROOKA, Yokohama Kanagawa (JP); Kazuya FUKASE, Hachioji Tokyo (JP); Shintaro NAKANO, Kawasaki Kanagawa (JP); Yuya MAEDA, Kawasaki Kanagawa (JP); Shuichi TORIYAMA, Yokohama Kanagawa (JP); Nobuki KANREI, Yokohama Kanagawa (JP)

(73) Assignee: KABUSHIKI KAISHA TOSHIBA, Tokyo (JP)

(21) Appl. No.: 14/663,351

(22) Filed: Mar. 19, 2015

(30) Foreign Application Priority Data
Sep. 30, 2014 (JP) 2014-201878

(51) Int. Cl. H01L 29/786; H01L 23/00

(52) U.S. Cl. CPC H01L 29/7869; H01L 23/564

(57) ABSTRACT

A semiconductor device according to an embodiment, includes a gate electrode, a first dielectric film, a first oxide semiconductor film, a second dielectric film, a source electrode, a source wire, a drain electrode, and a drain wire. The source wire is arranged on the second dielectric film, and connected to the source electrode. The drain wire is arranged on the second dielectric film, and connected to the drain electrode. At least one of the source wire and the drain wire includes a fringe portion sticking out above a channel region. A barrier film that suppresses intrusion of hydrogen is arranged being in contact with at least one of an upper surface and a lower surface of the fringe portion. A region where the barrier film is not formed is included above the channel region.

### CROSS-REFERENCE TO RELATED APPLICATION

This application is based upon and claims the benefit of priority from Japanese Patent Application No. 2014-201878 filed on Sep. 30, 2014 in Japan, the entire contents of which are incorporated herein by reference.

### FIELD

Embodiments described herein relate generally to a semiconductor device.

### BACKGROUND

Semiconductor devices using a compound semiconductor as a material are expected to realize excellent characteristics, which cannot be realized by semiconductor devices using silicon as a material. In recent years, a thin film transistor (TFT) using an oxide semiconductor film such as InGaZnO that is an oxide of indium (In), gallium (Ga), and zinc (Zn) has been developed. It is known that the InGaZnO thin film transistor exhibits n-type conductivity, can be easily manufactured at a low temperature of 300° C. or less, has large carrier mobility, and has a low off-state current. Therefore, the InGaZnO thin film transistor is expected not only for an application to a liquid crystal panel, but also for use as a high-performance thin film transistor in a silicon LSI.

In a manufacturing process of a silicon LSI, a process called hydrogen sintering is widely and typically used for improvement of stability and reliability of silicon MOS transistor characteristics. To be specific, the hydrogen sintering process is a process of performing, in the final process of a device forming process, thermal treatment of 350 to 450° C. in a forming gas (for example, N₂:H₂=1:1), and terminating a dangling bond that serves as an interface state of a silicon-dielectric film interface with hydrogen. Therefore, when the thin film transistor of an oxide semiconductor is included as a configuration element of the silicon LSI, the number of carriers in a channel region of the oxide semiconductor varies, resulting in a cause of a decrease in resistance of the film, and a decrease in a threshold voltage of the thin film transistor, due to the introduction of hydrogen in the hydrogen sintering process. Further, in a structure including a film that serves as a hydrogen barrier on the entire surface of the channel of the thin film transistor of an oxide semiconductor, hydrogen contained in the oxide semiconductor layer or a peripheral film stays without performing outward diffusion, in the fabricating process. This may also be the cause of a decrease in resistance of the oxide semiconductor film, and a decrease in a threshold of the thin film transistor.

### BRIEF DESCRIPTION OF THE DRAWINGS

FIG. 1 is a cross sectional view illustrating a configuration of a semiconductor device in a first embodiment;

FIGS. 2A to 2D are diagrams illustrating an example of distribution of hydrogen concentration in a comparative example of the first embodiment;

FIGS. 3A and 3B are examples of graphs illustrating the distribution of the hydrogen concentration in the comparative example of the first embodiment;

FIG. 4 is another example of a graph illustrating the distribution of the hydrogen concentration in the first embodiment and the comparative example;

FIG. 5 is a flowchart illustrating principal processes of a method for fabricating a semiconductor device in the first embodiment;

FIGS. 6A to 6D are process cross sectional views of the method for fabricating a semiconductor device in the first embodiment;

FIGS. 7A to 7C are process cross sectional views of the method for fabricating a semiconductor device in the first embodiment;

FIG. 8 is a cross sectional view illustrating a configuration of a semiconductor device in a second embodiment;

FIG. 9 is a cross sectional view illustrating a configuration of a semiconductor device in a third embodiment;

FIG. 10 is a cross sectional view illustrating a configuration of a semiconductor device in a fourth embodiment;

FIG. 11 is a cross sectional view illustrating a configuration of a semiconductor device in a fifth embodiment;

FIG. 12 is a cross sectional view illustrating a configuration of a semiconductor device in a sixth embodiment;

FIG. 13 is a cross sectional view illustrating a configuration of a semiconductor device in a seventh embodiment;

FIG. 14 is a cross sectional view illustrating a configuration of a semiconductor device in an eighth embodiment;

FIG. 15 is a cross sectional view illustrating a configuration of a semiconductor device in a ninth embodiment;

FIG. 16 is a cross sectional view illustrating a configuration of a semiconductor device in a tenth embodiment;

FIG. 17 is a cross sectional view illustrating a configuration of a semiconductor device in an eleventh embodiment;

FIGS. 18A to 18D are diagrams illustrating examples of distribution of hydrogen concentration in a comparative example (1) of the eleventh embodiment;

FIGS. 19A to 19D are diagrams illustrating examples of distribution of hydrogen concentration in a comparative example (2) of the eleventh embodiment;

FIGS. 20A to 20D are diagrams illustrating examples of distribution of hydrogen concentration in the eleventh embodiment;

FIGS. 21A and 21B are examples of graphs illustrating the distribution of the hydrogen concentration of when materials having different work functions are used for metal wires on source (S)/drain (D) electrodes in the eleventh embodiment;

FIG. 22 is a diagram illustrating potential energy in each film when a temperature is made variable in the comparative example of the eleventh embodiment;

FIG. 23 is a diagram illustrating potential energy in each film when a temperature is made variable in the eleventh embodiment; and

FIG. 24 is a diagram illustrating an example of relationship between a potential margin amount and the work function in the eleventh embodiment.

### DETAILED DESCRIPTION

A semiconductor device according to an embodiment, includes a gate electrode, a first dielectric film, a first oxide semiconductor film, a second dielectric film, a source electrode, a source wire, a drain electrode, and a drain wire. The first dielectric film is arranged on the gate electrode. The first oxide semiconductor film is arranged on the first dielectric film. The second dielectric film is arranged on the first oxide semiconductor film. The source electrode is arranged in the second dielectric film, and connected to the first oxide semiconductor film. The source wire is arranged on the second dielectric film, and connected to the source electrode. The drain electrode is arranged in the second dielectric film, and connected to the first oxide semiconductor film. The drain wire is arranged on the second dielectric film, and connected to the drain electrode. At least one of the source wire and the drain wire includes a fringe portion sticking out above a channel region. A barrier film that suppresses intrusion of hydrogen is arranged being in contact with at least one of an upper surface and a lower surface of the fringe portion. A region where the barrier film is not formed is included above the channel region.

A semiconductor device according to an embodiment, includes a gate electrode, a first dielectric film, an oxide semiconductor film, a second dielectric film, a source electrode, a source wire, a drain electrode, and a drain wire. The first dielectric film is arranged on the gate electrode. The oxide semiconductor film is arranged on the first dielectric film. The second dielectric film is arranged on the oxide semiconductor film. The source electrode is arranged in the second dielectric film, and connected to the oxide semiconductor film. The source wire uses a material having a work function larger than a material used as the source electrode, is arranged on the second dielectric film, and is connected to the source electrode. The drain electrode is arranged in the second dielectric film, and connected to the oxide semiconductor film. The drain wire uses a material having a work function larger than a material used as the drain electrode, is arranged on the second dielectric film, and is connected to the drain electrode. The materials used as the source wire and the drain wire have the work function larger than 4.5.

Hereinafter, in embodiments, a semiconductor device that can be operated as a transistor, and is also favorable as a configuration element of a silicon LSI will be described.

### First Embodiment

Hereinafter, in a first embodiment, “is provided on something” includes not only a case of being provided being directly in contact with the something, but also a case in which another layer or film is inserted therebetween. Further, “provided facing something” includes not only a case of being provided on or under something being directly in contact with the something, but also a case in which another layer or film is inserted therebetween.

The first embodiment will be described with reference to the drawings.

Note that the drawings are schematic or conceptual drawings, and the relationship between the thickness and the width of portions, and a ratio of the sizes of the portions are not the same as actual ones. Further, mutual dimensions and ratios maybe differently expressed from one another among the drawings, even when the same portion is expressed.

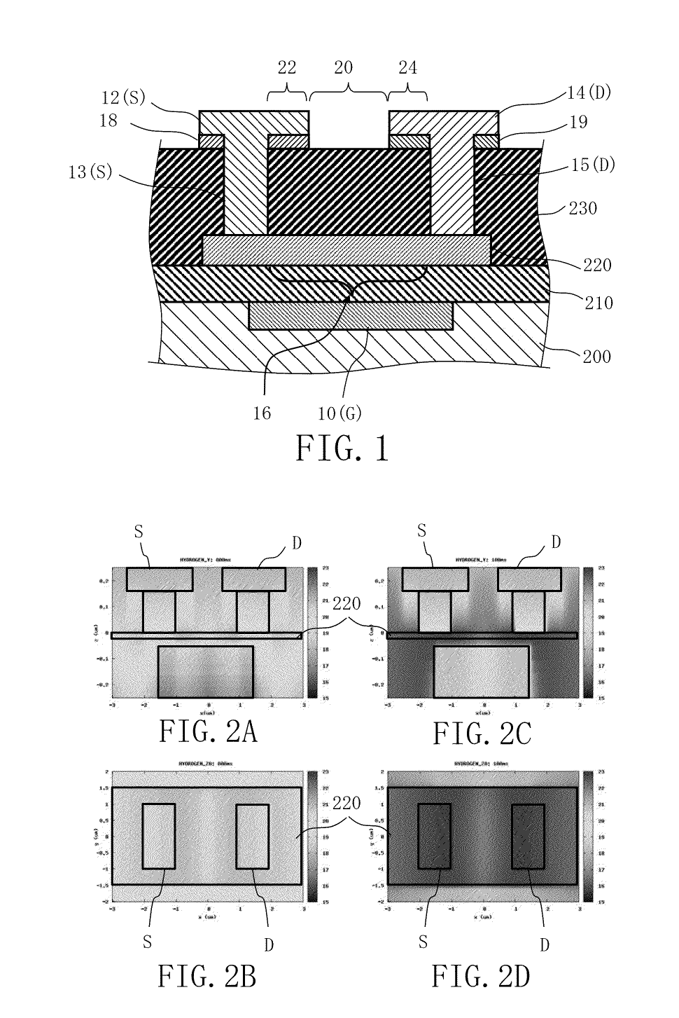

FIG. 1 is a cross sectional view illustrating a configuration of a semiconductor device in the first embodiment. In FIG. 1, as the semiconductor device, an example of a bottom gate-type (inversely-staggered type) thin film transistor (TFT) using an oxide semiconductor film such as InGaZnO film (IGZO film) is illustrated. In FIG. 1, a gate electrode 10 is formed on a surface of a dielectric film 200 formed on a substrate. As the dielectric film 200, a film containing silicon oxide (SiOₓ) or silicon nitride (SiNₓ) is used. As the gate electrode 10, a metal film containing tungsten (W), molybdenum (Mo), copper (Cu), tantalum (Ta), or aluminum (Al) is used. As the gate electrode 10, titanium nitride (TiN) or tantalum nitride (TaN) maybe used. As the gate electrode 10, an aluminum alloy may be used. The aluminum alloy contains aluminum as a main component, and is subjected to measures against hillocks. Further, a side surface of the gate electrode 10 maybe inclined to a laminating direction. That is, the side surface of the gate electrode 10 may formed in a tapered manner. The side surface of the gate electrode 10 is formed in a tapered manner, so that coating characteristics of a dielectric film 210 formed on the gate electrode 10 are enhanced. When the coating characteristics are enhanced, a leak current can be suppressed. In the example of FIG. 1, the gate electrode 10 is embedded in the dielectric film 200 such that a surface (upper surface) of the gate electrode 10 is formed at the same height position as an upper surface of the dielectric film 200. In the example of FIG. 1, a case in which the gate electrode 10 is formed in the same layer as a predetermined wire of a multilayer interconnection layer is assumed. Therefore, other wire layers, a semiconductor element, and the like may be formed in the substrate and the dielectric film 200. However, the embodiment is not limited to this configuration, and the gate electrode 10 may be formed on the dielectric film 200.

A gate dielectric film 210 (first dielectric film) is arranged on the gate electrode 10. The gate dielectric film 210 is formed on the gate electrode 10 and the dielectric film 200. The gate dielectric film 210 is, for example, a film containing silicon oxide (SiOₓ), aluminum oxide (AlₓO_{y}), silicon nitride (SiNₓ), or silicon oxynitride (SiOₓN_{y}). As the gate dielectric film 210, a laminated film formed of two or more films of silicon oxide, aluminum oxide, silicon nitride, and silicon oxynitride maybe used. An oxide semiconductor film 220 (first oxide semiconductor film) is formed on the gate dielectric film 210. The oxide semiconductor is in a monocrystalline, polycrystalline, or non-crystalline (amorphous) state, for example, and contains at least any of indium (In), gallium (Ga), and zinc (Zn). For example, as the oxide semiconductor, ternary metal oxide such as InGaZnO (hereinafter, may be called IGZO) is used. As the oxide semiconductor, binary metal oxide such as InGaO may be used. InGaWO or InGaSiO containing at least tungsten (W) or silicon (Si) maybe used. Further, as the oxide semiconductor, quaternary metal oxide such as InSnGaZnO or InAlGaZnO containing at least tin (Sn) or aluminum (Al) may be used. In any case, component ratios of the metal and elements other than the metal contained as main components are arbitrary.

Here, to be specific, as the oxide semiconductor, InGaZn-based oxide containing In, Ga, and Zn is used. The InGaZn-based oxide is an oxide containing indium, gallium, and zinc as the main components, and the component ratios of these metals are arbitrary. Further, a metal or another element other than the metals of indium, gallium, and zinc may be contained. If an InGaZnO film is used as the oxide semiconductor film 220, for example, resistance at the time of non-electric field is substantially large, and an off-state current can be made substantially small. Further, the mobility of the carrier can be enhanced.

The oxide semiconductor film 220 serves as a channel layer of the thin film transistor. When the oxide semiconductor film 220 is a layer containing IGZO, the oxide semiconductor film 220 is formed by a sputter process using IGZO4 where composition ratios of IGZO is In:Ga:Zn:O=1:1:1:4, as a target.

A dielectric film 230 (second dielectric film) is arranged on the oxide semiconductor film 220. The dielectric film 230 is a film that protects the upper surface of the oxide semiconductor film 220 from process damage and the like at the time of forming the electrode/wire with respect to the oxide semiconductor film 220. The dielectric film 230 is, for example, a film containing silicon oxide, or tetra ethyl ortho silicate (TEOS). As the dielectric film 230, a laminated film of silicon oxide and TEOS may be used.

Further, on one end side of the oxide semiconductor film 220, a source electrode 13 is arranged in the dielectric film 230, and is electrically connected to the one end side of the oxide semiconductor film 220. The source electrode 13 is connected to the oxide semiconductor film 220 at a position where at least a part of the source electrode 13 overlaps with one end portion of the gate electrode 10 in a gate length direction.

Further, on the other end side of the oxide semiconductor film 220, a drain electrode 15 is arranged in the dielectric film 230, and is connected to the other end side of the oxide semiconductor film 220. The drain electrode 15 is connected to the oxide semiconductor film 220 at a position where at least a part of the drain electrode 15 overlaps with the other end portion of the gate electrode 10 in the gate length direction.

The source electrode 13 and the drain electrode 15 are configured from a metal material film. For example, a metal film containing molybdenum (Mo), titanium (Ti), tantalum (Ta), tungsten (W), or aluminum (Al) is used. Molybdenum nitride (MoN), titanium nitride (TiN), or tantalum nitride (TaN) may be used. As the source electrode 13 and the drain electrode 15, a laminated film of two or more films of these conductive materials maybe used. A film containing indium tin oxide (ITO) or zinc oxide (ZnO) may be used. Alternatively, the source electrode 13 and the drain electrode 15 may be configured from a metal material film as a main material, and a barrier metal film (not illustrated) that coats a side surface and a bottom surface of the metal material film.

A source wire 12 connected to the source electrode 13 is arranged on the dielectric film 230. Similarly, a drain wire 14 connected to the drain electrode 15 is arranged on the dielectric film 230. The source wire 12 is formed sticking out to the side of a channel region 16. In other words, the source wire 12 has a fringe portion 22 that sticks out to the channel region 16 side. Similarly, the drain wire 14 is formed sticking out to a side of the channel region 16. In other words, the drain wire 14 has a fringe portion 24 that sticks out to the channel region 16 side. The source wire 12 and the drain wire 14 are configured from a metal material film. For example, a metal film containing molybdenum (Mo), titanium (Ti), tantalum (Ta), tungsten (W), or aluminum (Al) is used. Molybdenum nitride (MoN), titanium nitride (TiN), or tantalum nitride (TaN) may be used. As the source wire 12 and the drain wire 14, a laminated film of two or more films of these conductive materials may be used. A film containing indium tin oxide (ITO) or zinc oxide (ZnO) may be used. Alternatively, the source wire 12 and the drain wire 14 may be configured from a metal material film as the main material, and a barrier metal film (not illustrated) that coats the side surface and the bottom surface of the metal material film. Note that the source wire 12 and the source electrode 13 may be formed of different materials, or it is favorable if the source wire 12 and the source electrode 13 are integrally formed of the same material. Similarly, the drain wire 14 and the drain electrode 15 may be formed of different materials, or it is favorable if the drain wire 14 and the drain electrode 15 are integrally formed of the same material. Further, it is favorable if the source wire 12 and the drain wire 14 are formed of the same material at the same time because man-hour of processing is not increased. Similarly, it is favorable if the source electrode 13 and the drain electrode 15 are formed of the same material at the same time because man-hour of processing is not increased.

Note that the example of FIG. 1 illustrates a case in which both of the source wire 12 and the drain wire 14 have the fringe portions 22 and 24 sticking out to the channel region 16 sides. However, the embodiment is not limited to the example. Only one of the source wire 12 and the drain wire 14 may have one of the fringe portions 22 and 24 sticking out to the channel region 16 sides.

In the first embodiment, a barrier film 18 (predetermined film) that suppresses intrusion of hydrogen (H) is arranged being in contact with a back surface (lower surface) of the source wire 12. Similarly, a barrier film 19 (predetermined film) that suppresses intrusion of hydrogen (H) is arranged being in contact with a lower surface of the drain wire 14. In the example of FIG. 1, the barrier film 18 is arranged closely adhering between the lower surface of the source wire 12 and the dielectric film 230. Especially, the barrier film 18 is arranged closely adhering to the entire lower surface of the source wire 12 above the channel region 16. Similarly, the barrier film 19 is arranged closely adhering between the lower surface of the drain wire 14 and the dielectric film 230. Especially, the barrier film 19 is arranged closely adhering to the entire lower surface of the drain wire 14 above the channel region 16. Note that a region 20 where the barrier films 18 and 19 are not formed is included above the channel region 16.

Here, in a process of fabricating a silicon LSI, the hydrogen sintering process of 350° C. is performed in a forming gas (for example, N₂:H₂=1:1), for example, after the process of forming the metal wire that serves as the source wire 12 and the drain wire 14, for improvement of stability and reliability of characteristics of a silicon MOS transistor manufactured on a silicon substrate. The hydrogen sintering process is a process of terminating a dangling bond that serves as an interface state of a silicon-dielectric film interface with hydrogen. With the introduction of hydrogen, the hydrogen concentration is increased in a part of a region in a channel region of the oxide semiconductor film 220, and a decrease in resistance of the oxide semiconductor layer is caused, may be resulting in a cause of transistor malfunction of the thin film transistor.

FIGS. 2A to 2D are diagrams illustrating examples of distribution of hydrogen concentration in a thin film transistor in a comparative example of the first embodiment. FIGS. 2A to 2D illustrate a result of a state in which hydrogen falls from an upper surface to an InGaZnO thin film transistor as a monovalent hydrogen ion (H⁺), and is propagated with drift diffusion, the result being analyzed using technology computer aided design (TCAD). Even in a state where a bias voltage is not applied to an electrode terminal, potential distribution and electric field distribution arising from a work function and an electric constant unique to configuration materials are caused. In FIGS. 2A to 2D, in the comparative example, a case in which metal wires on source (S)/drain (D) electrodes have fringe portions sticking out to channel region sides is illustrated. Further, the comparative example has a configuration in which the barrier films 18 and 19 illustrated in FIG. 1 are not arranged. FIG. 2A illustrates distribution of hydrogen concentration in a cross section of the InGaZnO thin film transistor in a transition state of the drift diffusion of hydrogen. FIG. 2B illustrates distribution of hydrogen concentration in a plane of the InGaZnO film of the InGaZnO thin film transistor in the transition state of the drift diffusion of hydrogen. FIG. 2C illustrates distribution of hydrogen concentration in the cross section of the InGaZnO thin film transistor at timing when the drift diffusion of hydrogen reaches a steady state. FIG. 2D illustrates distribution of hydrogen concentration in the plane of the InGaZnO film of the InGaZnO thin film transistor at timing when the drift diffusion of hydrogen reaches the steady state. FIGS. 2A to 2D indicate that, in any case, a concentration difference is caused in the hydrogen concentration of the channel region, instead of uniform concentration, and the hydrogen concentration in the InGaZnO film (oxide semiconductor film 220) under the fringe portions of the source wire and the drain wire sticking out to the channel region sides is higher than the hydrogen concentration in a central portion of the channel region of the oxide semiconductor film 220 above which the fringe portions of the source wire and the drain wire do not exist.

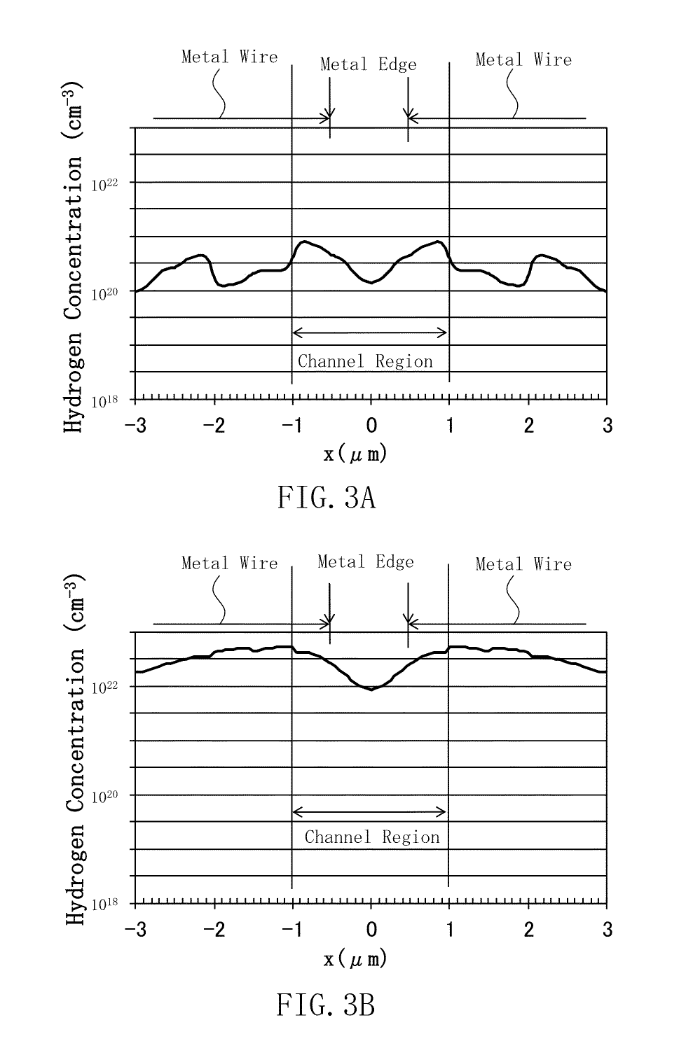

FIGS. 3A and 3B are examples of graphs illustrating the distribution of the hydrogen concentration in the thin film transistor in the comparative example of the first embodiment. FIG. 3A illustrates the hydrogen concentration on a vertical axis and a position in the channel length direction on a horizontal axis, and illustrates the hydrogen concentration of the InGaZnO film (oxide semiconductor film 220) in the transition state of the drift diffusion of hydrogen illustrated in FIGS. 2A and 2B. FIG. 3B illustrates the hydrogen concentration on the vertical axis and a position in the channel length direction on the horizontal axis, and illustrates the hydrogen concentration of the InGaZnO film (oxide semiconductor film 220) in the steady state of the drift diffusion of hydrogen illustrated in FIGS. 2C and 2D. FIGS. 3A and 3B indicate that, in any case, a concentration difference is caused in the hydrogen concentration in the channel region, instead of uniform concentration, and the hydrogen concentration in the InGaZnO film (oxide semiconductor film 220) under the fringe portions of the source wire and the drain wire sticking out to the channel region side is higher than the hydrogen concentration in the central portion of the channel region of the oxide semiconductor film 220 above which the fringe portions of the source wire and the drain wire do not exist.

As described above, in the case of the configuration of the comparative example, the hydrogen concentration is increased in the region portion under the fringe portions of the source wire and the drain wire, in the channel region 16 of the oxide semiconductor film 220. Therefore, a decrease in resistance of the oxide semiconductor film 220 is caused, resulting in a cause to bring about a decrease in a threshold voltage of the thin film transistor and transistor malfunction.

Therefore, in the first embodiment, as illustrated in FIG. 1, the barrier film 18 (first barrier film) is arranged to come in contact with the lower surface of the source wire 12. Similarly, the barrier film 19 (second barrier film) is arranged to come in contact with the lower surface of the drain wire 14. As the barrier films 18 and 19, a dielectric film, semiconductor film, and an oxide conductive film can be used. As the dielectric film, it is favorable to use aluminum oxide (AlₓO_{y}), silicon nitride (SiNₓ), or a laminated film of aluminum oxide and silicon nitride, for example. As the semiconductor film, it is favorable to use a oxide semiconductor film, for example, an InGaZnO film (second oxide semiconductor film) containing at least any of indium (In), gallium (Ga), and zinc (Zn). As the oxide conductive film, it is favorable to use an InSnO film (ITO film) or zinc oxide (ZnO), for example. The above oxide or nitride is arranged under the fringe portions 22 and 24 of the source wire 12 and the drain wire 14 as the barrier films, whereby the barrier films take in hydrogen intruding from above at the time of the hydrogen sintering process, and can prevent the intrusion of hydrogen to the dielectric film 230 side. Therefore, an increase in the hydrogen concentration in the region under the fringe portions 22 and 24 of the source wire 12 and the drain wire 14, in the channel region 16 of the oxide semiconductor film 220, can be prevented.

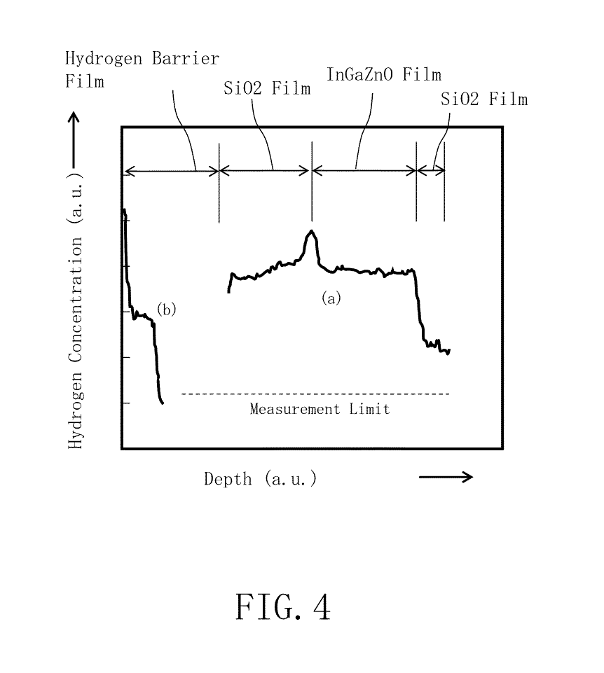

FIG. 4 is another example of graphs illustrating the distribution of the hydrogen concentration in the first embodiment and the comparative example. (a) in the drawing illustrates an example of the hydrogen concentration under the fringe portions of the source/drain wires in the comparative example in which the hydrogen barrier films are not arranged. (b) illustrates an example of the hydrogen concentration under the fringe portions of the source/drain wires in the first embodiment in which the hydrogen barrier films 18 and 19 are arranged. As illustrated in (a) of FIG. 4, in the comparative example in which the hydrogen barrier films are not arranged, it is found that the hydrogen concentration in the upper surface of the InGaZnO film (oxide semiconductor film 220) under the fringe portion is increased. In contrast, in the first embodiment, as illustrated in (b) of FIG. 4, it is found that the hydrogen concentration is low below the hydrogen barrier films 18 and 19 (at the oxide semiconductor film 220 sides), and hydrogen is not introduced to the dielectric film 230 and the InGaZnO film (oxide semiconductor film 220), through the hydrogen sintering process.

In a structure having the hydrogen barrier film on the entire region above the channel region 16 of the oxide semiconductor transistor, hydrogen contained in the oxide semiconductor film 220 or in the interlayer dielectric 230 stays without performing outward diffusion, in the fabricating process. Such situation becomes a cause to bring about the decrease in the resistance in the oxide semiconductor film 220, the decrease in the threshold of the oxide semiconductor thin film transistor, and the transistor malfunction. Therefore, in the first embodiment, as illustrated in FIG. 1, the region 20 on which the barrier films 18 and 19 are not formed is included above the channel region 16. With the configuration, hydrogen in the film is outwardly diffused, and a favorable transistor operation of the oxide semiconductor thin film transistor can be realized.

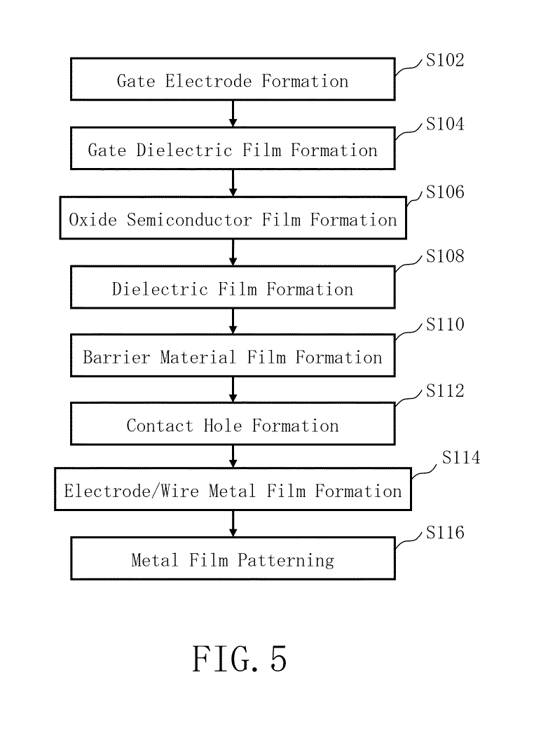

FIG. 5 is a flowchart illustrating principal processes of a method of fabricating a semiconductor device in the first embodiment. In FIG. 5, the method for fabricating a semiconductor device in the first embodiment performs a series of processes including a gate electrode forming process (S102), a gate dielectric film forming process (S104), an oxide semiconductor film forming process (S106), a dielectric film forming process (S108), a barrier material film forming process (5110), an opening forming process (S112), an electrode/wire material film forming process (S114), and an electrode/wire material patterning process (S116).

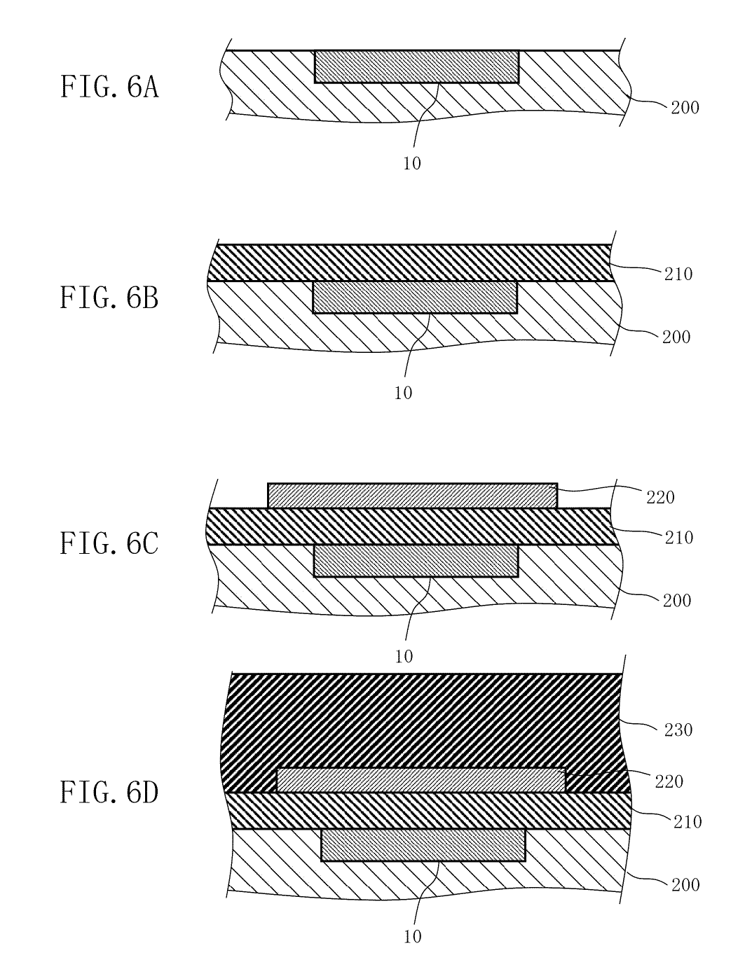

FIGS. 6A to 6D illustrate process cross sectional views of the method for fabricating a semiconductor device in the first embodiment. FIGS. 6A to 6D illustrate the processes from the gate electrode forming process (S102) to the dielectric film forming process (S108) of FIG. 5. The processes after the above processes will be described below.

In FIG. 6A, as the gate electrode forming process (S102), the gate electrode 10 is formed in the dielectric film 200. A part of the metal wire of the multilayer interconnection may be included beside the transistor, assuming that the thin film transistor (TFT) using the oxide semiconductor film is made in the multilayer interconnection layer. In the example of FIG. 6A, the gate electrode 10 is embedded and manufactured in the dielectric film by a damascene process. For example, an opening (groove) for the gate electrode 10 is formed in the dielectric film 200. Then, the gate electrode material is deposited on the dielectric film 200 to fill in the opening. After being deposited, the extra gate electrode material that overflows outside the opening may just be polished and removed by a chemical-mechanical polishing (CMP) method. In the process, the gate electrode 10 is formed. As the material of the gate electrode 10, a metal film containing copper (Cu), tantalum (Ta), tungsten (W), molybdenum (Mo), tantalum nitride (TaN), titanium nitride (TiN), or Al (aluminum) can be used. Note that, when Cu is used, to prevent diffusion of Cu to the dielectric film 200 and the like, a barrier metal film is formed on a side surface and a bottom surface of the opening, and the gate electrode 10 may just be formed to fill in the opening through the barrier metal film. Further, as the dielectric film 200, for example, a film containing silicon oxide (SiOₓ) or silicon nitride (SiNₓ) is formed on a silicon substrate made of a silicon wafer. Although not illustrated, a wire and various elements may be formed on the dielectric film 200.

Note that, in the example of FIG. 6A, the embedded structure by the damascene process has been illustrated. However, the embodiment is not limited to the example. The gate electrode 10 may be formed by being patterned by an etching method after depositing the gate electrode material on the dielectric film 200 by a sputter process or the like. Further, the side surface of the gate electrode 10 may be inclined in the laminating direction. That is, the side surface of the gate electrode 10 may be formed in a tapered manner.

In FIG. 6B, as the gate dielectric film forming process (S104), the gate dielectric film 210 is formed on the gate electrode 10, with a film thickness of 2 to 50 nm, using a chemical vapor deposition (CVD) method. Here, the gate dielectric film 210 is formed with the film thickness of 15 nm, for example. As the material of the gate dielectric film 210, it is favorable to use silicon oxide (SiO₂), aluminum oxide (AlₓO_{y}), silicon nitride (SiNₓ), silicon oxynitride (SiOₓN_{y}) or the like. As the gate dielectric film 210, a laminated film of two or more films of silicon oxide, aluminum oxide, silicon nitride, and silicon oxynitride may be used. As a forming method, it is favorable to use a plasma CVD method or an atomic layer vapor phase growing (atomic layer deposition: ALD or an atomic layer chemical vapor deposition: ALCVD) method.

In FIG. 6C, as the oxide semiconductor film forming process (S106), the oxide semiconductor film 220 is formed on the gate dielectric film 210 with the film thickness of 10 to 30 nm, using the sputter process. Here, the oxide semiconductor film 220 is formed with the thickness of 30 nm, for example. Following that, the oxide semiconductor film 220 having a predetermined size is formed, by patterning the oxide semiconductor film 220 to remain an active region by an etching method. It is favorable to form the width of the oxide semiconductor film 220 in the gate length direction larger than the width of the gate electrode 10. The oxide semiconductor is in a monocrystalline, polycrystalline, or non-crystalline (amorphous) state. As the material of the oxide semiconductor film 220, for example, at least any of indium (In), gallium (Ga), and zinc (Zn) is contained, as described above. As the oxide semiconductor, for example, binary metal oxide such as InGaO, or ternary metal oxide such as IGZO is used. InGaWO or InGaSiO containing at least tungsten (W) or silicon (Si) may be used. Further, as the oxide semiconductor, quaternary metal oxide such as InSnGaZnO or InAlGaZnO containing at least tin (Sn) or aluminum (Al) may be used. In any case, the component ratios of the metal or the elements other than the metal contained as the main components are arbitrary.

When the oxide semiconductor film 220 is a layer containing IGZO, the oxide semiconductor film 220 is formed by the sputter process using IGZO4 where the composition ratios of IGZO is In:Ga:Zn:O=1:1:1:4, as a target. Note that the component ratios of the metals of indium, gallium, and zinc are arbitrary, and metals other than indium, gallium, and zinc, or elements other than the metals may be contained.

In FIG. 6D, as the dielectric film forming process (S108), the dielectric film 230 is formed on the oxide semiconductor film 220 and the gate dielectric film 210, with the film thickness of 30 to 200 nm, by a CVD method. Here, the dielectric film 230 is formed on the gate dielectric film 210, with the film thickness of 150 nm, for example. For example, the dielectric film 230 is a film containing silicon oxide, or tetra ethyl ortho silicate (TEOS). As the dielectric film 230, a laminated film of silicon oxide and TEOS may be used. As a forming method, it is favorable to use the plasma CVD method or the atomic layer vapor phase growing. The dielectric film 230 is formed to coat the oxide semiconductor film 220, and serves as a protection film of the oxide semiconductor film 220.

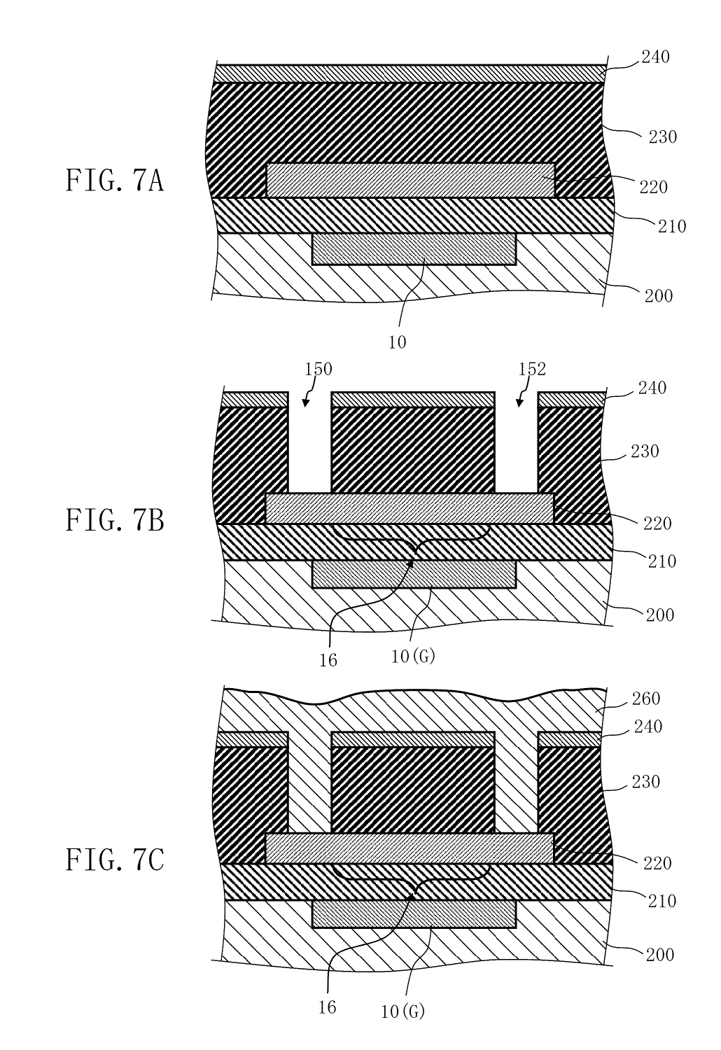

FIGS. 7A to 7C illustrate process cross sectional views of the method for fabricating a semiconductor device in the first embodiment. FIGS. 7A to 7C illustrate processes from the barrier material film forming process (5110) to the electrode/wire material film forming process (S114) of FIG. 5.

In FIG. 7A, as the barrier material film forming process (S110), for example, the barrier material film 240 (an example of the oxide film) is formed on the dielectric film 230, with the film thickness of 5 to 50 nm, using the sputter process. Here, the barrier material film 240 is formed with the film thickness of 30 nm, for example. As the barrier material film 240, as described above, a dielectric film, a semiconductor film, and an oxide conductive film can be used. As the dielectric film, it is favorable to use aluminum oxide (AlₓO_{y}), silicon nitride (SiNₓ), or a laminated film of aluminum oxide and silicon nitride, for example. As the semiconductor film, it is favorable to use an oxide semiconductor layer, for example, a film such as an InGaZnO film containing at least any of indium (In), gallium (Ga), and zinc (Zn). As the oxide conductive film, it is favorable to use an ITO film (indium tin oxide), zinc oxide (ZnO), or a laminated film of the ITO film (indium tin oxide) and zinc oxide.

When the semiconductor film or the conductive film is used as the barrier material film 240, to control a resistance value of the film, elements different from the main components such as an adequate amount of nitrogen or Al may be contained, in addition to the main components.

In FIG. 7B, as the opening forming process (S112), openings 150 and 152 are formed to penetrate the barrier material film 240 and the dielectric film 230 from the barrier material film 240 to the surface of the oxide semiconductor film 220. The opening 150 (contact hole) for source is formed in a position, at least a part of which overlaps with the one end portion of the gate electrode 10 in the gate length direction. At the same time, the opening 152 (contact hole) for drain is formed in a position, at least a part of which overlaps with the other end portion of the gate electrode 10 in the gate length direction. The openings 150 and 152 are formed with a width of 1 μm or less, as the size for an electrode. The openings 150 and 152 are substantially vertically formed in the surface of the substrate, by removing, by an anisotropic etching method, the exposed barrier material film 240 and dielectric film 230 from the substrate, in which a resist pattern is formed on the barrier material film 240 through lithography processes such as a resist coating process and an exposing process (not illustrated). As an example, the openings 150 and 152 may just be formed by a reactive ion etching (RIE) method.

In FIG. 7C, as the electrode/wire material film forming process (S114), an electrode/wire material film 260 (an example of the conductive film) is formed on the barrier material film 240 to completely fill in the openings 150 and 152, with the film thickness of 50 to 100 nm, using the sputter process, for example. Here, the electrode/wire material film 260 is formed with the film thickness of 50 nm, for example. As the electrode/wire material film 260, a metal film containing molybdenum (Mo), titanium (Ti), tantalum (Ta), tungsten (W), or aluminum (Al) is used, for example. Molybdenum nitride (MoN), titanium nitride (TiN), or tantalum nitride (TaN) maybe used. Further, a laminated film of two or more films of these conductive materials may be used. A film containing indium tin oxide (ITO) or zinc oxide (ZnO) may be used. Alternatively, the electrode/wire material film 260 may be configured from a metal material film as the main material, and a barrier metal film (not illustrated) that coats the side surface and the bottom surface of the metal material film. Then, the electrode/wire material film 260 is planarized by a CMP method.

As the patterning process (S116), the source wire 12, the barrier film 18, the drain wire 14, and the barrier film 19, having the fringe portions 22 and 24 at the channel region 16 sides as illustrated in FIG. 1 are formed, by patterning the electrode/wire material film 260 and the barrier material film 240 such that only the metal wire forming region is remained, by lithography and an etching method (not illustrated). In other words, the electrode/wire material film 260 and the barrier material film 240 are patterned to have the fringe portions 22 and 24 sticking out to the central portion sides of the oxide semiconductor film 220. The source wire 12, the barrier film 18, the drain wire 14, and the barrier film 19 are substantially vertically formed on the surface of the substrate 200, by removing, by an anisotropic etching method, the exposed electrode/wire material film 260 and barrier material film 240 from the substrate 200, in which the resist pattern is formed on the electrode/wire material film 260 through the lithography processes such as the resist coating process and the exposing process (not illustrated). As an example, the source wire 12, the barrier film 18, the drain wire 14, and the barrier film 19 may just be formed by the RIE method. At this time, the source wire 12 and the barrier film 18, and the drain wire 14 and the barrier film 19 are formed in mutually self-aligning patterns. Further, the source electrode 13 and the drain electrode 15 are formed at the same time.

As described above, in the first embodiment, even when the source wire 12 and the drain wire 14 have the fringe portions 22 and 24 at the channel region 16 side, the barrier films 18 and 19 that suppress intrusion of hydrogen are arranged below the lower surfaces of the source wire 12 and the drain wire 14, whereby an increase in the hydrogen concentration in the channel region of the oxide semiconductor film 220 under the fringe portion can be suppressed. As a result, variation of the number of carriers and a decrease in the resistance in the channel region of the oxide semiconductor film 220 can be suppressed. Therefore, a decrease in the threshold voltage of the thin film transistor and transistor malfunction can be suppressed.

### Second Embodiment

In the first embodiment, a configuration of arranging the barrier films 18 and 19 on the lower surfaces of the source wire 12 and the drain wire 14 has been described. However, an embodiment is not limited to the configuration. In a second embodiment, another configuration will be described.

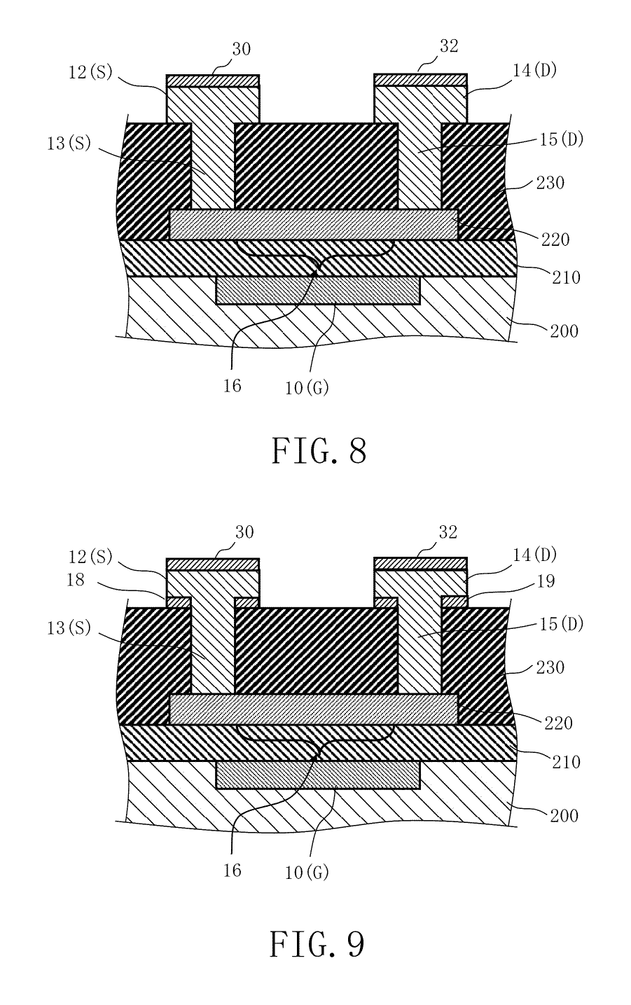

FIG. 8 is a cross sectional view illustrating a configuration of a semiconductor device in the second embodiment. FIG. 8 is similar to FIG. 1 except that barrier films 30 and 32 (predetermined films) are arranged closely adhering to upper surfaces of a source wire 12 and a drain wire 14, instead of arranging barrier films 18 and 19 on lower surfaces of the source wire 12 and the drain wire 14. A material of the barrier films 30 and 32 is similar to that of the barrier films 18 and 19 in the first embodiment. Details not described below are similar to those in the first embodiment.

After a dielectric film 230 is formed, an opening 150 (contact hole) for source and an opening 152 (contact hole) for drain are formed in the dielectric film 230 to penetrate the dielectric film 230. Then, an electrode/wire material film 260 is formed on the dielectric film 230 to completely fill in the openings 150 and 152. Then, after the electrode/wire material film 260 is planarized, a barrier material film that is the same type of the barrier material film 240 in the first embodiment is formed on the electrode/wire material film 260, with a film thickness of 5 to 50 nm, using a sputter process, for example. Here, the barrier material film is formed with the film thickness of 30 nm, for example. Then, the source wire 12, the barrier film 30 (first barrier film), the drain wire 14, and the barrier film 32 (second barrier film) having fringe portions at sides of a channel region 16 as illustrated in FIG. 8 may just be formed, by patterning the barrier material film and the electrode/wire material film 260 such that only a metal wire forming region is remained, by lithography and an etching method (not illustrated). The remained barrier material film serves as the barrier films 30 and 32, and the source wire 12 and the barrier film 30, and the drain wire 14 and the barrier film 32 are formed in mutually self-aligning patterns.

As illustrated in FIG. 8, with the configuration of arranging the barrier films 30 and 32 on the upper surfaces of the source wire 12 and the drain wire 14, an increase in hydrogen concentration in the channel region 16 of an oxide semiconductor film 220 under the fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Third Embodiment

In the first and second embodiments, configurations of arranging the barrier films 18 and 19 (barrier films 30 and 32) on one of the lower surfaces and the upper surfaces of the source wire 12 and the drain wire 14 have been described. However, an embodiment is not limited to the configurations. In a third embodiment, another configuration will be described.

FIG. 9 is a cross sectional view illustrating a configuration of a semiconductor device in the third embodiment. In FIG. 9, barrier films 18 and 19 (predetermined films) are arranged closely adhering to lower surfaces of a source wire 12 and a drain wire 14, and barrier films 30 and 32 (predetermined films) are arranged closely adhering to upper surfaces of the source wire 12 and the drain wire 14. Other configurations are similar to those of FIG. 1. A material of the barrier films 30 and 32 is similar to that of the barrier films 18 and 19 in the first embodiment. Details not especially described below are similar to those in the first embodiment.

Similarly to the second embodiment, after an electrode/wire material film 260 is planarized, a second barrier material film is formed on the electrode/wire material film 260. Then, the second barrier material film, the electrode/wire material film 260, and a barrier material film 240 may just be patterned such that only a metal wire forming region is remained, by lithography and an etching method (not illustrated).

As illustrated in FIG. 9, with the configuration of arranging the barrier films 18 and 19, and the barrier films 30 and 32 on the upper surfaces and the lower surfaces of the source wire 12 and the drain wire 14, an increase in hydrogen concentration in a channel region 16 in an oxide semiconductor film 220 under fringe portions can be suppressed, similarly to the first and second embodiments. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Fourth Embodiment

In the first and second embodiments, configurations of arranging the barrier films 18 and 19 (barrier films 30 and 32) on the lower surfaces and/or the upper surfaces of the source wire 12 and the drain wire 14 have been described. However, an embodiment is not limited to the configurations. In a fourth embodiment, another configuration will be described.

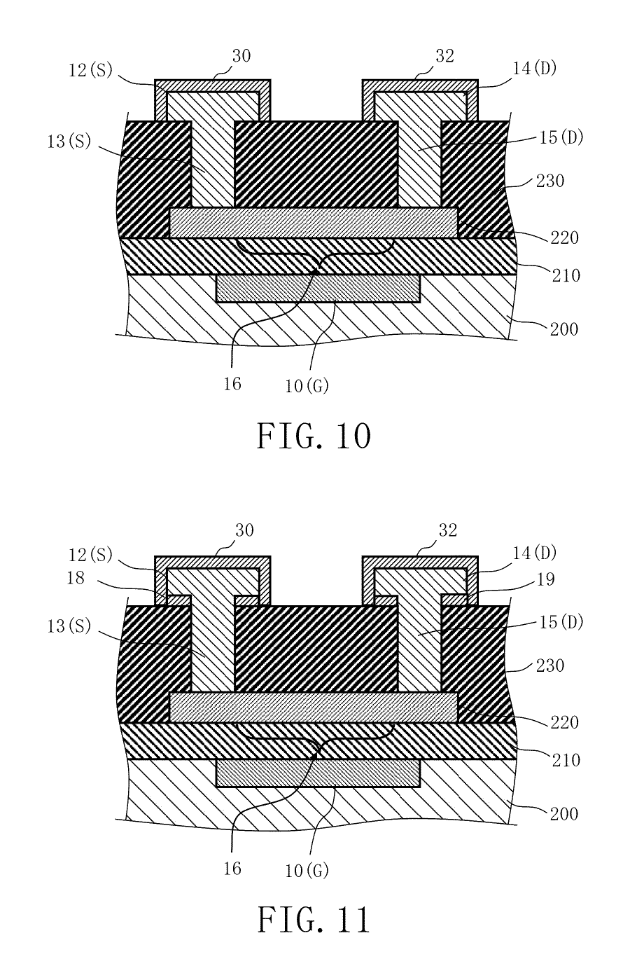

FIG. 10 is a cross sectional view illustrating a configuration of a semiconductor device in the fourth embodiment. In FIG. 10, barrier films 30 and 32 (predetermined films) are arranged closely adhering to upper surfaces and side surfaces of a source wire 12 and a drain wire 14. Other configurations are similar to those of FIG. 1. A material of the barrier films 30 and 32 is similar to that of the barrier films 18 and 19 in the first embodiment. Details not especially described below are similar to those in the first embodiment.

After a dielectric film 230 is formed, an opening 150 (contact hole) for source and an opening 152 (contact hole) for drain are formed. Then, an electrode/wire material film 260 is formed on a dielectric film 230 to completely fill in the openings 150 and 152. Then, the electrode/wire material film 260 is patterned such that only a metal wire forming region is remained. Then, a barrier material film similar to the barrier material film 240 in the first embodiment is formed to coat the electrode/wire material film 260, and patterning may just be performed such that the barrier material film is remained on upper surfaces and side surfaces of the electrode/wire material film 260. The film patterns with the remained barrier material film serve as the barrier films 30 and 32.

As illustrated in FIG. 10, with the configuration of arranging the barrier films 30 an 32 on the upper surfaces and the side surfaces of the source wire 12 and the drain wire 14, an increase in hydrogen concentration in a channel region 16 of an oxide semiconductor film 220 under fringe portions can be suppressed, similarly to the first and second embodiments. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Fifth Embodiment

In the fourth embodiment, a configuration of arranging the barrier films 30 and 32 on the upper surfaces and the side surfaces of the source wire 12 and the drain wire 14 has been described. However, an embodiment is not limited to the configuration. In a fifth embodiment, another configuration will be described.

FIG. 11 is a cross sectional view illustrating a configuration of a semiconductor device in the fifth embodiment. In FIG. 11, barrier films 18 and 30 (predetermined films) are arranged closely adhering to an upper surface, a lower surface, and a side surface of a source wire 12. Barrier films 19 and 32 (predetermined films) are arranged closely adhering to an upper surface, a lower surface and a side surface of a drain wire 14. Other configurations are similar to those of FIG. 1. In the fifth embodiment, the barrier films 18 and 19, and the barrier films 30 and 32 coat the entire surfaces of the source wire 12 and the drain wire 14, in a region on an oxide semiconductor film 220. A material of the barrier films 30 and 32 is similar to that of the barrier films 18 and 19 in the first embodiment. Details not especially described below are similar to those in the first embodiment.

After a barrier material film 240 is formed, an opening 150 (contact hole) for source, and an opening 152 (contact hole) for drain are formed. Then, an electrode/wire material film 260 is formed on the barrier material film 240 to completely fill in the openings 150 and 152. Then, the electrode/wire material film 260 and the barrier material film 240 are patterned such that only a metal wire forming region is remained. Then, a second barrier material film similar to the barrier material film 240 is formed to coat the electrode/wire material film 260, and patterning may just be performed such that the second barrier material film is remained on upper surfaces and side surfaces of the electrode/wire material film 260. The remained barrier material film 240 servers as the barrier films 18 and 19. The remained second barrier material film serves as the barrier films 30 and 32.

As illustrated in FIG. 11, with the configuration of arranging the barrier films 18 and 19, and the barrier films 30 and 32 on the upper surfaces, the lower surfaces, and the side surfaces of the source wire 12 and the drain wire 14, an increase in hydrogen concentration in a channel region 16 of an oxide semiconductor film 220 under fringe portions can be suppressed, similarly to the first and second embodiments. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Sixth Embodiment

In the first to fifth embodiments, configurations of arranging the barrier films 18 and 19 (barrier films 30 and 32) on the upper surfaces, the lower surfaces and/or side surfaces of the source wire 12 and the drain wire 14 have been described. However, an embodiment is not limited to the configurations. In a sixth embodiment, another configuration will be described.

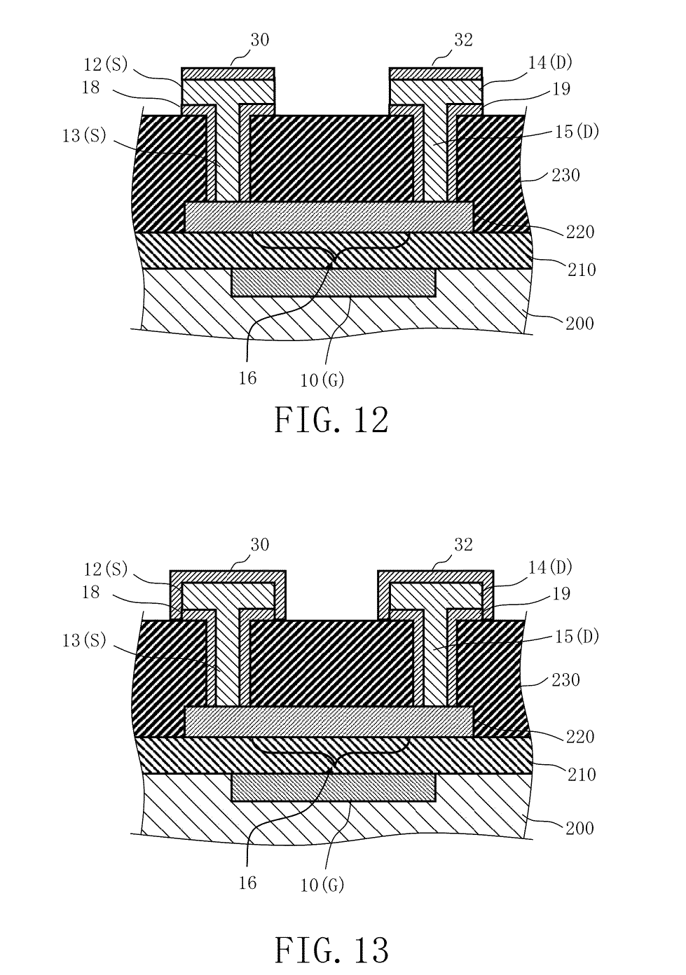

FIG. 12 is a cross sectional view illustrating a configuration of a semiconductor device in the sixth embodiment. In FIG. 12, barrier films 18 and 19 (predetermined films) are arranged closely adhering to lower surfaces of a source wire 12 and a drain wire 14, and side surfaces of a source electrode 13 and a drain electrode 15, and barrier films 30 and 32 (predetermined films) are arranged closely adhering to upper surfaces of the source wire 12 and the drain wire 14. Other configurations are similar to those of FIG. 1. A material of the barrier films 30 and 32 is similar to that of the barrier films 18 and 19 in the first embodiment. Details not especially described below are similar to those in the first embodiment.

After a barrier material film 240 is formed, openings 150 and 152 are formed. Then, the barrier material film 240 is formed on an upper surface of the barrier material film 240, and inner walls and bottom surfaces of the openings 150 and 152 again. Then, the barrier material film 240 on the bottom surfaces of the openings 150 and 152 are removed, by performing anisotropic etch back in the vertical direction. Then, an electrode/wire material film 260 is formed on the barrier material film 240 to completely fill in the openings 150 and 152. Then, a second barrier material film is further formed on the electrode/wire material film 260. Then, patterning may just be performed to remain regions of the source wire 12 and the drain wire 14 and eliminate other second barrier material film, electrode/wire material film 260, and barrier material film 240. The remained barrier material film 240 serves as the barrier films 18 and 19. The remained second barrier material film serves as the barrier films 30 and 32.

As illustrated in FIG. 12, with the configuration of arranging the barrier films 18 and 19 on the lower surfaces of the source wire 12 and the drain wire 14, and the side surfaces of the source electrode 13 and the drain electrode 15, and the barrier films 30 and 32 closely adhering to the upper surfaces of the source wire 12 and the drain wire 14, an increase in hydrogen concentration in a channel region 16 of an oxide semiconductor film 220 under fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Seventh Embodiment

In a seventh embodiment, another configuration will be described.

FIG. 13 is a cross sectional view illustrating a configuration of a semiconductor device in the seventh embodiment. In FIG. 13, barrier films 18 and 19 (predetermined films) are arranged closely adhering to lower surfaces of a source wire 12 and a drain wire 14, and side surfaces of a source electrode 13 and a drain electrode 15, and barrier films 30 and 32 (predetermined films) are arranged closely adhering to upper surfaces and side surfaces of the source wire 12 and the drain wire 14. Other configurations are similar to those of FIG. 1. A material of the barrier films 30 and 32 is similar to that of the barrier films 18 and 19 in the first embodiment. Details not especially described below are similar to those in the first embodiment.

After a barrier material film 240 is formed, openings 150 and 152 are formed. Then, the barrier material film 240 is formed on an upper surface of the barrier material film 240, and inner walls and bottom surfaces of the openings 150 and 152 again. Then, the barrier material film 240 on the bottom surfaces of the openings 150 and 152 are removed, by performing anisotropic etch back in the vertical direction. Then, an electrode/wire material film 260 is formed on the barrier material film 240 to completely fill in the openings 150 and 152. Then, patterning is performed to remain regions of the source wire 12 and the drain wire 14. Following that, a second barrier film is formed to coat upper surfaces and side surfaces of the electrode/wire material film 260. Then, patterning may just be performed to remain the second barrier material film on the upper surfaces and the side surfaces of the electrode/wire material film 260. The remained barrier material film 240 serve as the barrier films 18 and 19. The remained second barrier material film serves as the barrier films 30 and 32.

As illustrated in FIG. 13, with the configuration of arranging the barrier films 18 and 19 on the lower surfaces of the source wire 12 and the drain wire 14 and the side surfaces of the source electrode 13 and the drain electrode 15, and the barrier films 30 and 32 on the upper surfaces and the side surfaces of the source wire 12 and the drain wire 14, an increase in hydrogen concentration in a channel region 16 of an oxide semiconductor film 220 under fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Eighth Embodiment

In the first to seventh embodiments, configurations of not forming a barrier film between the oxide semiconductor film 220 and the source electrode 13 and between the oxide semiconductor film 220 and the drain electrode 15 have been described. However, an embodiment is not limited to the configurations. In an eighth embodiment, another configuration will be described.

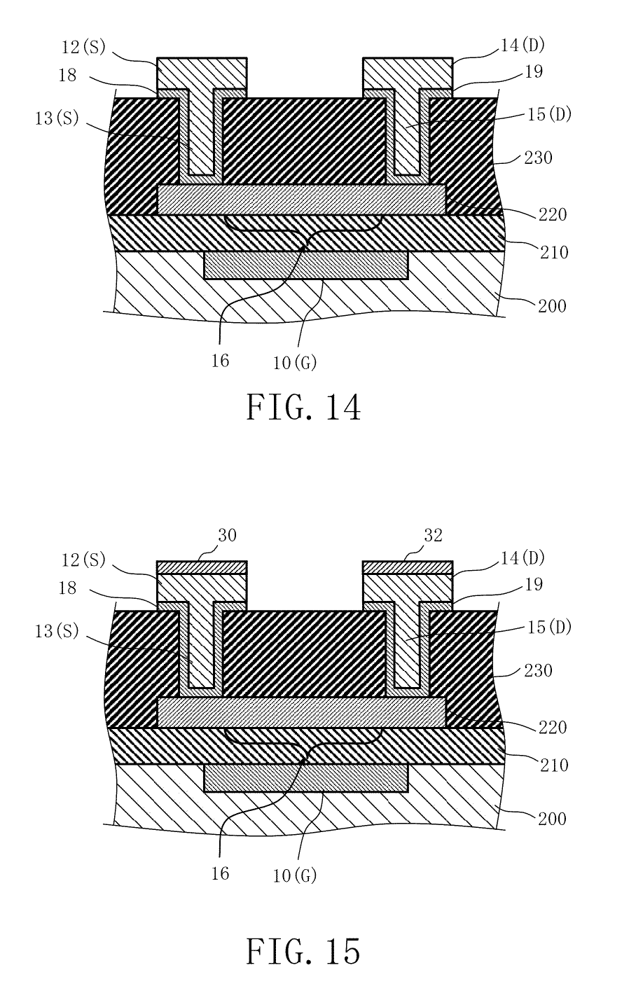

FIG. 14 is a cross sectional view illustrating a configuration of a semiconductor device in the eighth embodiment. In FIG. 14, barrier films 18 and 19 (predetermined films) are arranged closely adhering to lower surfaces of a source wire 12 and a drain wire 14, and side surfaces and bottom surfaces of a source electrode 13 and a drain electrode 15. Other configurations are similar to those of FIG. 1. Details not especially described below are similar to those in the first embodiment.

After a dielectric film 230 is formed, openings 150 and 152 are formed. Then, a barrier material film 240 is formed on an upper surface of the dielectric film 230, and inner walls and bottom surfaces of the openings 150 and 152. Then, an electrode/wire material film 260 is formed on the barrier material film 240 to completely fill in the openings 150 and 152. Then, patterning may just be performed to remain regions of the source wire 12 and the drain wire 14. The remained barrier material film 240 serves as the barrier films 18 and 19. As described above, in the eighth embodiment, the barrier film 18 (first barrier film) is formed between the source electrode 13 and an oxide semiconductor film 220. The barrier film 19 (second barrier film) is formed between the drain electrode 15 and the oxide semiconductor film 220. In the eighth embodiment, as the barrier material film 240, a semiconductor film or a conductive film is used. To be specific, as the semiconductor film, it is favorable to use an oxide semiconductor layer, for example, a film such as an InGaZnO film containing at least any of indium (In), gallium (Ga), and zinc (Zn). As the oxide conductive film, for example, it is favorable to use an ITO film (indium tin oxide), zinc oxide (ZnO), or a laminated film of the ITO film and zinc oxide. Since electrical connections between the oxide semiconductor film 220 and the source electrode 13 and between the oxide semiconductor film 220 and the drain electrode 15 are to be formed, a dielectric film is not used as the barrier material film 240. Especially, as the barrier material film 240, it is more favorable to use the same type of material as the oxide semiconductor film 220. By use of the same type of material, an increase in resistance between the barrier material film 240 and the oxide semiconductor film 220 can be avoided. Further, even if an oxygen deficiency portion arising from a reaction between the metal materials that configure the source electrode 13 and the drain electrode 15, and the oxide semiconductor is generated in the oxide semiconductor, the second oxide semiconductor film as the barrier material film 240 lies between the source electrode 13 and the oxide semiconductor film 220 and between the drain electrode 15 and the oxide semiconductor film 220, whereby likelihood of diffusion of the generated oxygen deficiency portion to a channel region 16 of the oxide semiconductor film 220 to bring about change of a threshold voltage of the transistor can be avoided.

As illustrated in FIG. 14, with the configuration of arranging the barrier films 18 and 19 on the lower surfaces of the source wire 12 and the drain wire 14, and the side surfaces and the bottom surfaces of the source electrode 13 and the drain electrode 15, an increase in hydrogen concentration in the channel region 16 of the oxide semiconductor film 220 under fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Ninth Embodiment

In a ninth embodiment, another configuration will be described.

FIG. 15 is a cross sectional view illustrating a configuration of a semiconductor device in the ninth embodiment. In FIG. 15, barrier films 18 and 19 (predetermined films) are arranged closely adhering to lower surfaces of a source wire 12 and a drain wire 14, and side surfaces and bottom surfaces of a source electrode 13 and a drain electrode 15, and barrier films 30 and 32 (predetermined films) are arranged on upper surfaces of the source wire 12 and the drain wire 14. Other configurations are similar to those of FIG. 1. Details not especially described below are similar to those in the eighth embodiment.

After an electrode/wire material film 260 is formed, a second barrier material film is formed on the electrode/wire material film 260. Then, patterning may just be performed to remain regions of the source wire 12 and the drain wire 14. The remained second barrier material film serves as the barrier films 30 and 32. Note that, as a material of the second barrier material film (barrier films 30 and 32), a dielectric film made of aluminum oxide (AlₓO_{y}), silicon nitride (SiNₓ), or a laminated film of aluminum oxide and silicon nitride can be used, in addition to a semiconductor film or a conductive film similar to the barrier material film 240, unlike the barrier material film 240 (barrier films 18 and 19) that do not use the dielectric film but use a semiconductor film or a conductive film.

As illustrated in FIG. 15, with the configuration of arranging the barrier films 18 and 19 closely adhering to the lower surfaces of the source wire 12 and the drain wire 14 and the side surfaces and the bottom surfaces of the source electrode 13 and the drain electrode 15, and barrier films 30 and 32 on the upper surfaces of the source wire 12 and the drain wire 14, an increase in hydrogen concentration in a channel region 16 of an oxide semiconductor film 220 under fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Tenth Embodiment

In a tenth embodiment, another configuration will be described.

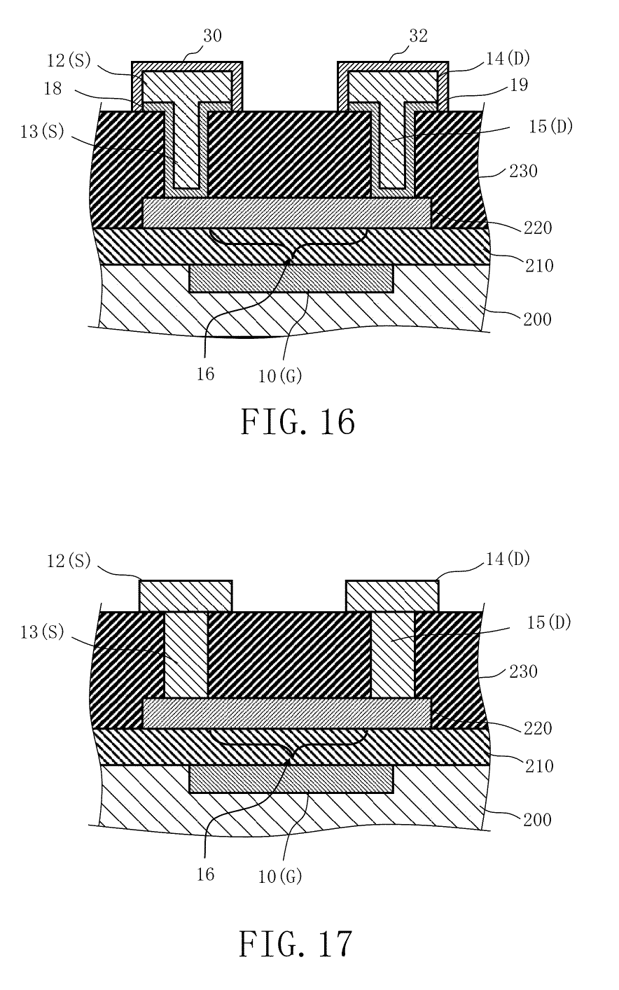

FIG. 16 is a cross sectional view illustrating a configuration of a semiconductor device in the tenth embodiment. In FIG. 16, barrier films 18 and 19 (predetermined films) are arranged closely adhering to lower surfaces of a source wire 12 and a drain wire 14, and side surfaces and bottom surfaces of a source electrode 13 and a drain electrode 15, and barrier films 30 and 32 (predetermined films) are arranged on upper surfaces and side surfaces of the source wire 12 and the drain wire 14. Other configurations are similar to those of FIG. 1. Details not especially described below are similar to those in the ninth embodiment.

After an electrode/wire material film 260 is formed, patterning is performed to remain regions of the source wire 12 and the drain wire 14. Then, a second barrier material film is formed to coat the electrode/wire material film 260. Then, patterning may just be performed to remain the second barrier material film on an upper surfaces and side surfaces of the electrode/wire material film 260. The remained second barrier material film serves as the barrier films 30 and 32. Note that, as a material of the second barrier material film (barrier films 30 and 32), a dielectric film made of aluminum oxide (AlₓO_{y}), silicon nitride (SiNₓ), or a laminated film of aluminum oxide and silicon nitride can be used, in addition to a semiconductor film or a conductive film similar to the barrier material film 240, unlike the barrier material film 240 (barrier films 18 and 19) that do not use the dielectric film but use a semiconductor film or a conductive film.

As illustrated in FIG. 16, with the configuration of arranging the barrier films 18 and 19 on the lower surfaces of the source wire 12 and the drain wire 14 and the side surfaces and bottom surfaces of the source electrode 13 and the drain electrode 15, and the barrier films 30 and 32 on the upper surfaces and the side surfaces of the source wire 12 and the drain wire 14, an increase in hydrogen concentration in a channel region 16 of an oxide semiconductor film 220 under fringe portions can be suppressed, similarly to the first embodiment. As a result, variation of the number of carriers and a decrease in the resistance in the channel region 16 of the oxide semiconductor film 220 can be suppressed. Therefore, a decrease in the threshold voltage of the thin film transistor and transistor malfunction can be suppressed.

### Eleventh Embodiment

In the first to tenth embodiments, configurations of arranging the hydrogen barrier film on the lower surfaces and the upper surfaces of the source wire 12 and the drain wire 14 to suppress the intrusion of hydrogen have been described. A technique to suppress an increase in hydrogen concentration in a channel region of an oxide semiconductor film 220 is not limited thereto. In the eleventh embodiment, a configuration of selecting a combination of materials having different work functions to suppress the increase in hydrogen concentration in a channel region of an oxide semiconductor film 220 will be described.

FIG. 17 is a cross sectional view illustrating a configuration of a semiconductor device in the eleventh embodiment. FIG. 17 is similar to FIG. 1 except that barrier films 18 and 19 are not arranged, and a material used for a source wire 12 and a drain wire 14, and a material used for a source electrode 13 and a drain electrode 15 are different.

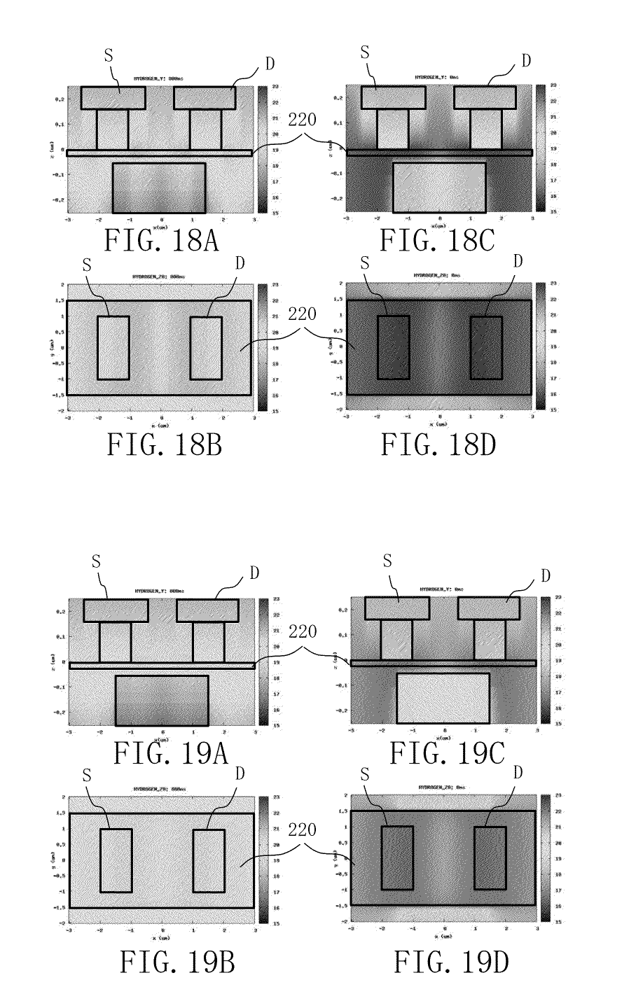

FIGS. 18A to 18D are diagrams illustrating examples of distribution of hydrogen concentration in a comparative example (1) of an eleventh embodiment. FIGS. 18A to 18D illustrate a result of a state in which hydrogen falls from an upper surface to an InGaZnO thin film transistor as a monovalent hydrogen ion (H⁻), and is propagated with drift diffusion, the result being analyzed using technology computer aided design (TCAD). Even in a state where a bias voltage is not applied to an electrode terminal, potential distribution and electric field distribution arising from a work function and an electric constant unique to configuration materials are caused. In FIGS. 18A to 18D, the comparative example (1) illustrates a case in which a material having a work function of 4.05 is used as metal wires on source (S)/drain (D) electrodes, and the metal wires have fringe portions striking out to channel region sides. Further, the comparative example (1) is a configuration of not arranging barrier films 18 and 19 as illustrated in FIG. 17. FIG. 18A illustrates distribution of hydrogen concentration in a cross section of an InGaZnO thin film transistor in a transition state of the drift diffusion of hydrogen. FIG. 18B illustrates distribution of hydrogen concentration in a plane of the InGaZnO film of the InGaZnO thin film transistor in the transition state of the drift diffusion of hydrogen. FIG. 18C illustrates distribution of hydrogen concentration in the cross section of the InGaZnO thin film transistor at timing when the drift diffusion of hydrogen reaches a steady state. FIG. 18D illustrates distribution of hydrogen concentration in the plane of the InGaZnO film of the InGaZnO thin film transistor at timing when the drift diffusion of hydrogen reaches the steady state. FIGS. 18A to 18D illustrate that, in any case, a concentration difference is caused in the hydrogen concentration of a channel region, instead of uniform concentration, and the hydrogen concentration in the InGaZnO film (oxide semiconductor film 220) under the fringe portions of the source wire and the drain wire sticking out to the channel region sides is higher than the hydrogen concentration in a central portion of the channel region of the oxide semiconductor film 220 above which the fringe portions of the source wire and the drain wire do not exist.

FIGS. 19A to 19D illustrate examples of distribution of hydrogen concentration in a comparative example (2) of the eleventh embodiment. In FIGS. 19A to 19D, the comparative example (2) illustrates a case of using a material having a work function of 4.33 as metal wires on source (S)/drain (D) electrodes. Other configurations are similar to those of the comparative example (1) of FIGS. 18A to 18D. FIG. 19A illustrates distribution of hydrogen concentration in a cross section of an InGaZnO thin film transistor in a transition state of the drift diffusion of hydrogen. FIG. 19B illustrates distribution of hydrogen concentration in a plane of the InGaZnO film of the InGaZnO thin film transistor in the transition state of the drift diffusion of hydrogen. FIG. 19C illustrates distribution of hydrogen concentration in the cross section of the InGaZnO transistor at timing when the drift diffusion of hydrogen reaches a steady state. FIG. 19D illustrates distribution of hydrogen in the plane of the InGaZnO film of the InGaZnO thin film transistor at timing when the drift diffusion of hydrogen reaches the steady state. FIGS. 19A to 19D illustrate that, in any case, a concentration difference is caused in the hydrogen concentration of a channel region, instead of uniform concentration, and the hydrogen concentration in the InGaZnO film (oxide semiconductor film 220) under the fringe portions of the source wire and the drain wire sticking out to the channel region sides is higher than the hydrogen concentration in a central portion of the channel region of the oxide semiconductor film 220 above which the fringe portions of the source wire and the drain wire do not exist.

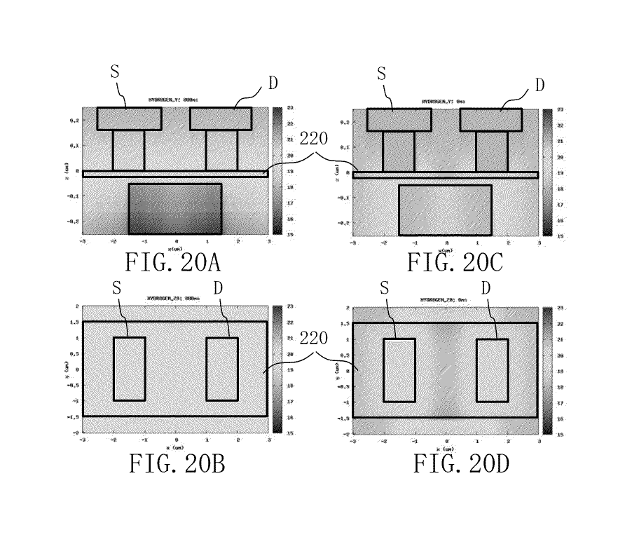

FIGS. 20A to 20D are diagrams illustrating examples of distribution of hydrogen concentration in the eleventh embodiment. In FIGS. 20A to 20D, the eleventh embodiment illustrates a case of using a material having a work function of 4.60 as metal wires on source (S)/drain (D) electrodes. Other configurations are similar to the comparative example (1) of FIGS. 18A to 18D. FIG. 20A illustrates distribution of hydrogen concentration in a cross section of an InGaZnO thin film transistor in a transition state of the drift diffusion of hydrogen. FIG. 20B illustrates distribution of hydrogen concentration in a plane of the InGaZnO film of the InGaZnO thin film transistor in the transition state of the drift diffusion of hydrogen. FIG. 20C illustrates distribution of hydrogen concentration in the cross section of the InGaZnO thin film transistor at timing when the drift diffusion of hydrogen reaches a steady state. FIG. 20D illustrates distribution of hydrogen concentration in the plane of the InGaZnO film of the InGaZnO thin film transistor at timing when the drift diffusion of hydrogen reaches the steady state. FIGS. 20A to 20D illustrate that, in any case, a concentration difference is caused in the hydrogen concentration of a channel region, instead of uniform concentration, and the hydrogen concentration in the InGaZnO film (oxide semiconductor film 220) under the fringe portions of the source wire and the drain wire sticking out to the channel region sides is not higher than the hydrogen concentration in a central portion of the channel region of the oxide semiconductor film 220 above which the fringe portions of the source wire and the drain wire do not exist.

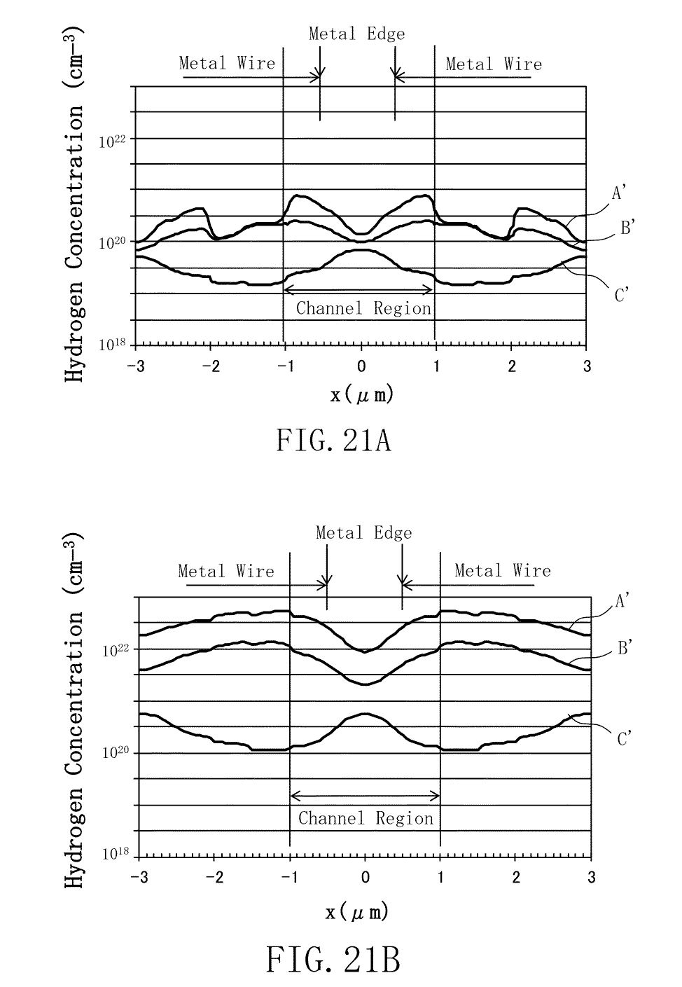

FIGS. 21A and 21B are examples of graphs illustrating the distribution of the hydrogen concentration when materials having different work functions are used as the metal wires on the source (S)/drain (D) electrodes in the eleventh embodiment. FIG. 21A illustrates the hydrogen concentration on the vertical axis and a position in a channel region length direction on the horizontal axis, and illustrates the hydrogen concentration of the InGaZnO film (oxide semiconductor film 220) in the transition state of the drift diffusion of hydrogen illustrated in FIGS. 18A and 18B, 19A and 19B, and 20A and 20B. FIG. 21B illustrates the hydrogen concentration on the vertical axis and a position in the channel length direction on the horizontal axis, and illustrates the hydrogen concentration of the InGaZnO film (oxide semiconductor film 220) in the steady state of the drift diffusion of hydrogen illustrated in FIGS. 18C and 18D, 19C and 19D, and 20C and 20D. The graph A′ illustrates a result of the metal wire having the work function of 4.05, illustrated in FIGS. 18A to 18D. The graph B′ illustrates a result of the metal wire having the work function of 4.33, illustrated in FIGS. 19A to 19D. The graph C′ illustrates a result of the metal wire having the work function of 4.60, illustrated in FIGS. 20A to 20D. Both of the cases where the work functions of the material used as the metal wire on the source (S)/drain (D) electrodes are 4.05 and 4.33 indicate that the hydrogen concentration in the InGaZnO film (oxide semiconductor film 220) under the fringe portions sticking out to the channel region sides is higher than the hydrogen concentration in the central portion of the channel region of the oxide semiconductor film 220. Meanwhile, the case where the work function of the material used as the metal wire is 4.60 indicates that the hydrogen concentration in the InGaZnO film (oxide semiconductor film 220) under the fringe portions sticking out to the channel region sides is lower than the hydrogen concentration in the central portion of the channel region of the oxide semiconductor film 220. Further, the case where the work function is 4.60 shows that the hydrogen concentration in the channel region of the oxide semiconductor film 220 is generally lower than that of the cases where the work functions are 4.05 and 4.33.

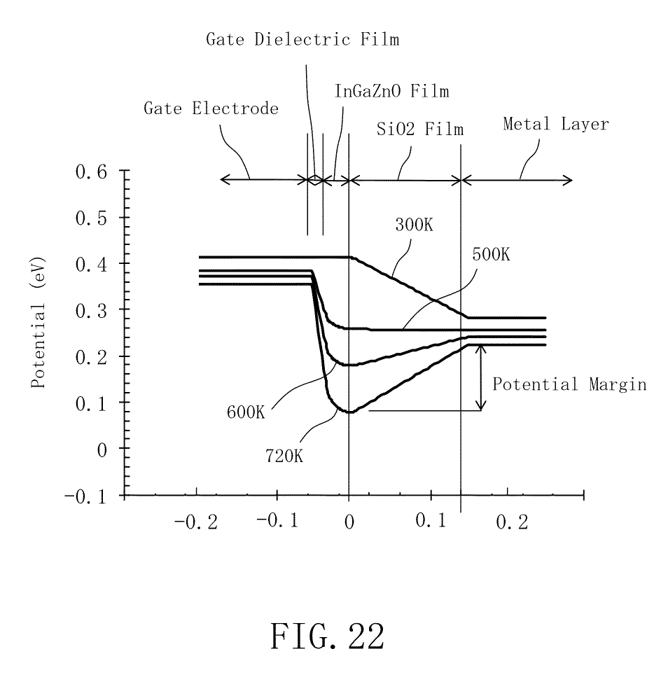

FIG. 22 is a diagram illustrating potential energy in each film when the temperature is made variable in the comparative example of the eleventh embodiment. The example of FIG. 22 illustrates the potential energy under each temperature of 300 to 720 K when the material having the work function of 4.33 is used as the metal wires on the source (S)/drain (D) electrodes. Further, FIG. 22 illustrates results of when focusing on the potential of the gate electrode, the gate dielectric film, the InGaZnO film (oxide semiconductor film 220), the upper dielectric film, and the metal wire layer under or in the fringe portions where the metal wires stick out to the channel region sides. In the drawing, a difference between the potential of the surfaces of the metal wires of the source/drain electrodes, and the potential on the surface side of the InGaZnO film under the fringe portions, in 720 K is illustrated as a potential margin amount with respect to the hydrogen diffusion. As illustrated in FIG. 22, under the temperature of 720 K, the potential energy on the surface of the InGaZnO film is smaller than that of the surface of the metal wire (a negative margin amount). Therefore, it is found that, when the hydrogen falls from an upper surface as the monovalent hydrogen ion (H⁺), and is propagated with drift diffusion, hydrogen is more easily taken in to the surface of the InGaZnO film than to the metal wire under the fringe portions.

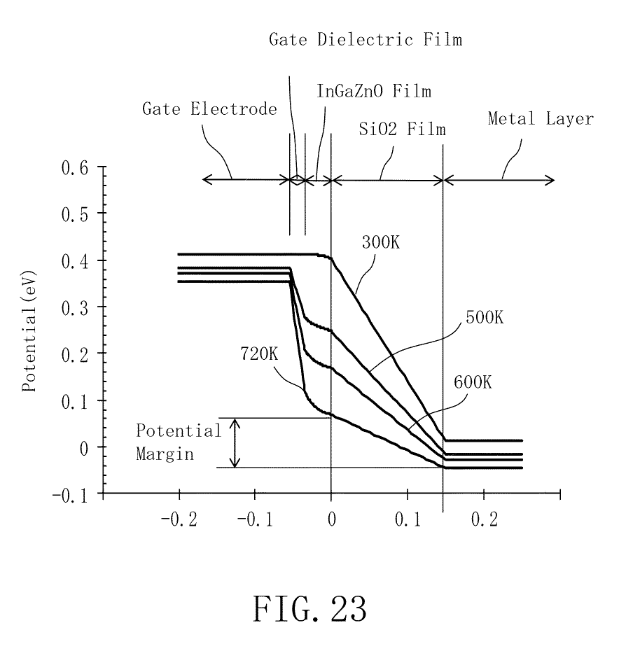

FIG. 23 illustrates a diagram illustrating potential energy in each film when the temperature is made variable in the eleventh embodiment. The example of FIG. 23 illustrates the potential energy under each temperature of 300 to 720 K when the material having the work function of 4.60 is used as the metal wires on the source (S)/drain (D) electrodes. Further, FIG. 23 illustrates results of when focusing on the potential of the gate electrode, the gate dielectric film, the InGaZnO film (oxide semiconductor film 220), the upper dielectric film, and the metal wire layer under or in the fringe portions where the metal wires stick out to the channel region sides, similarly to FIG. 22. In the drawing, a difference between the potential of the surfaces of the metal wires of the source/drain electrodes, and the potential on the surface side of the InGaZnO film under the fringe portions, in 720 K is illustrated as a potential margin amount with respect to the hydrogen diffusion. As illustrated in FIG. 23, under the temperature of 720 K, the potential energy on the surface of the InGaZnO film is larger than that of the surface of the metal wire (a positive margin amount). Therefore, it is found that, when the hydrogen falls from an upper surface as the monovalent hydrogen ion (H⁺), and is propagated with drift diffusion, hydrogen is less easily taken in to the surface of the InGaZnO film than to the metal wire under the fringe portions. Therefore, an increase in the hydrogen concentration can be suppressed in the InGaZnO film (oxide semiconductor film 220) under the fringe portions.

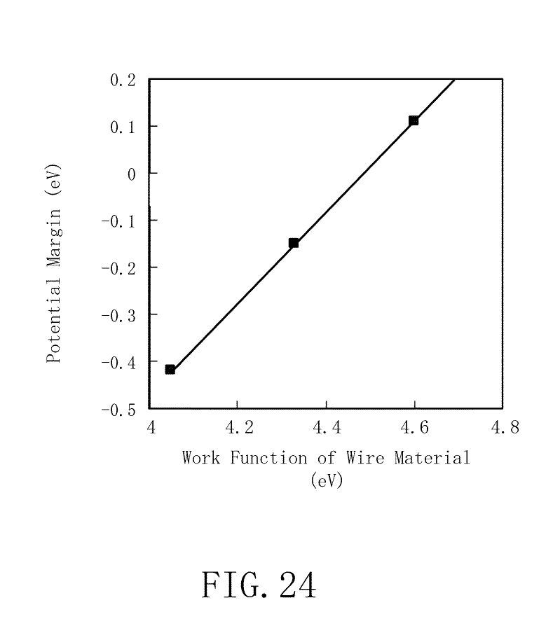

FIG. 24 is a diagram illustrating an example of relationship between the potential margin amount and the work function in the eleventh embodiment. FIG. 24 illustrates the potential margin amount on the vertical axis, and a value of the work function of the fringe portions on the horizontal axis. As illustrated in FIG. 24, when the value of the work function is made large, the potential margin amount can be made large in the positive direction. Therefore, the value of the work function is made large, whereby the increase in the hydrogen concentration in the InGaZnO film (oxide semiconductor film 220) under the fringe portions can be suppressed. Especially, the material having the work function larger than 4.5 is used as the metal wire of the source/drain electrodes, whereby variation of the number of carriers in the channel region of the oxide semiconductor film 220 is suppressed, and a decrease in resistance can be suppressed.

Therefore, in the eleventh embodiment, a material having a work function larger than 4.5 is used as the material of the source wire 12 and the drain wire 14.

As the material having the work function larger than 4.5 for the source wire 12 and the drain wire 14, it is favorable to select one from tungsten (W), titanium nitride (TiN), ruthenium (Ru), ruthenium oxide (RuO), nickel (Ni), tungsten nitride (WN), iridium (Ir), molybdenum nitride (MoN), tantalum nitride (TaN), and platinum (Pt), for example. However, the material is not limited thereto.

Meanwhile, as for the source electrode 13 and the drain electrode 15 being in contact with the InGaZnO film (oxide semiconductor film 220), it is desirable to use a metal having a work function smaller than the work function of the oxide semiconductor in order to realize favorable contact characteristics. In the case of the InGaZnO film, it is favorable to select one from molybdenum (Mo), tantalum (Ta), and titanium (Ti) as the material for the source electrode 13 and the drain electrode 15. However, the material is not limited thereto.

As described above, as the source wire 12 and the drain wire 14, a material having a larger work function than the material used for the source electrode 13 and the drain electrode 15, and having a work function larger than 4.5 is used. With the configuration, similarly to the first embodiment, an increase in the hydrogen concentration in the channel region of the oxide semiconductor film 220 under the fringe portions can be suppressed, through the hydrogen sintering process. As a result, the variation of the number of carriers and the decrease in resistance in the channel region of the oxide semiconductor film 220 can be suppressed. Therefore, a decrease in a threshold voltage of the thin film transistor and transistor malfunction can be suppressed.

The embodiments have been described with reference to specific examples. However, the present disclosure is not limited by these specific examples. In the above-described first to tenth embodiments, when the above-described semiconductor film or conductive film is used for the barrier films 18, 19, 30, and 32, an adequate amount of an element such as nitrogen or Al, which is different from the main components may be included, in addition to the main components, in order to control the resistance value of the film.

Further, all of semiconductor devices and methods for fabricating a semiconductor device that include the elements of the present disclosure, and design change of which can be appropriately performed by a person skilled in the art, are included in the scope of the present disclosure.

Further, techniques normally used in the semiconductor industry, for example, techniques of cleaning before and after a process, and the like can be included, although such techniques are omitted for simplification of the description.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein maybe made without departing from the spirit of the inventions. The accompanying claims and their equivalents are intended to cover such forms or modifications as would fall within the scope and spirit of the inventions.

What is claimed is:

1. A semiconductor device comprising:
a gate electrode;
a first dielectric film arranged on the gate electrode;
a first oxide semiconductor film arranged on the first dielectric film;
a second dielectric film arranged on the first oxide semiconductor film;
a source electrode arranged in the second dielectric film, and connected to the first oxide semiconductor film;
a source wire arranged on the second dielectric film, and connected to the source electrode;
a drain electrode arranged in the second dielectric film, and connected to the first oxide semiconductor film; and
a drain wire arranged on the second dielectric film, and connected to the drain electrode, wherein
at least one of the source wire and the drain wire includes a fringe portion sticking out above a channel region,
a barrier film that suppresses intrusion of hydrogen is arranged being in contact with at least one of an upper surface and a lower surface of the fringe portion, and
a region where the barrier film is not formed is included above the channel region.

2. The device according to claim 1, wherein the barrier film is further formed between at least one of the source electrode and the drain electrode, and the first oxide semiconductor film.

3. The device according to claim 2, wherein the barrier film is further formed on side surfaces of at least one of the source electrode and the drain electrode.

4. The device according to claim 2, wherein at least one of a second oxide semiconductor film and an oxide conductive film is used as the barrier film.

5. The device according to claim 2, wherein a same type of material is used as the barrier film and the first oxide semiconductor film.

6. The device according to claim 1, wherein the barrier film is arranged being in contact with the upper surface, the lower surface, and a side surface of the fringe portion.

7. The device according to claim 1, wherein the barrier film is further formed on side surfaces of at least one of the source electrode and the drain electrode, without being formed between the source electrode and the first oxide semiconductor film and between the drain electrode and the first oxide semiconductor film.

8. The device according to claim 1, wherein the barrier film is formed in a self-aligning pattern with at least one of the source wire and the drain wire, being in contact with a lower surface of at least one of the source wire and the drain wire.

9. The device according to claim 1, wherein the barrier film is formed in a self-aligning pattern with at least one of the source wire and the drain wire, being in contact with an upper surface of at least one of the source wire and the drain wire.

10. The device according to claim 1, wherein the source wire and the drain wire are integrally formed with the source electrode and the drain electrode, respectively.

11. The device according to claim 1, wherein at least one of a silicon nitride film and an aluminum oxide film is used as the barrier film.

12. The device according to claim 1, wherein a second oxide semiconductor film is used as the barrier film.

13. The device according to claim 12, wherein a film containing at least one of indium (In), gallium (Ga), and zinc (Zn) is used as the second oxide semiconductor film.

14. The device according to claim 13, wherein an InGaZnO film is used as the second oxide semiconductor film.

15. The device according to claim 1, wherein an oxide conductive film is used as the barrier film.

16. The device according to claim 15, wherein an ITO film or a ZnO film is used as the oxide conductive film.

17. A semiconductor device comprising:
a gate electrode;
a first dielectric film arranged on the gate electrode;
an oxide semiconductor film arranged on the first dielectric film;
a second dielectric film arranged on the oxide semiconductor film;
a source electrode arranged in the second dielectric film, and connected to the oxide semiconductor film;
a source wire using a material having a work function larger than a material used as the source electrode, arranged on the second dielectric film, and connected to the source electrode;
a drain electrode arranged in the second dielectric film, and connected to the oxide semiconductor film; and
a drain wire using a material having a work function larger than a material used as the drain electrode, arranged on the second dielectric film, and connected to the drain electrode, wherein
the materials used as the source wire and the drain wire have the work function larger than 4.5.

18. The device according to claim 17, wherein at least one of the source wire and the drain wire has a fringe portion sticking out above a channel region.

19. A semiconductor device comprising:
a gate electrode;
a first dielectric film arranged on the gate electrode;
a first oxide semiconductor film arranged on the first dielectric film;
a second dielectric film arranged on the first oxide semiconductor film;
a source electrode arranged in the second dielectric film, and connected to the first oxide semiconductor film;
a source wire arranged on the second dielectric film, and connected to the source electrode;
a drain electrode arranged in the second dielectric film, and connected to the first oxide semiconductor film; and
a drain wire arranged on the second dielectric film, and connected to the drain electrode, wherein
at least one of the source wire and the drain wire includes a fringe portion sticking out above a channel region,
a predetermined film using at least one of a silicon nitride film, an aluminum oxide film, a second oxide semiconductor film, and an oxide conductive film, being in contact with at least one of an upper surface and a lower surface of the fringe portion, is arranged, and
a region where the predetermined film is not formed is included above the channel region.

20. The device according to claim 19, wherein the second oxide semiconductor film is used as the predetermined film, and
a same type of material is used as the first oxide semiconductor film and the second oxide semiconductor film.
